(19) United States
(12) Patent Application Publication
(10) Pub. No.: US 2014/0377926 A1
(43) Pub. Date: Dec. 25, 2014

(54) METHOD FOR FABRICATING SEMICONDUCTOR DEVICE

(71) Applicant: SAMSUNG ELECTRONICS CO., LTD., Suwon-si (KR)

(72) Inventors: Tae-Gon KIM, Seoul (KR); Jong-Hoon Kang, Jong-Hoon (KR); Eun-Young Jo, Gyeonggi-do (KR); Gil-Heyun Choi, Seoul (KR); Han-Mei Choi, Seoul (KR)

(73) Assignee: SAMSUNG ELECTRONICS CO., LTD., Gyeonggi-do (KR)

(21) Appl. No.: 14/294,287

(22) Filed: Jun. 3, 2014

(30) Foreign Application Priority Data
Jun. 21, 2013 (KR) 10-2013-0071806

(51) Int. Cl. H01L 21/225; H01L 29/66

(52) U.S. Cl. CPC H01L 21/225; H01L 29/66795
USPC 438/289

(57) ABSTRACT

A fin type active pattern is formed on a substrate. The fin type active pattern projects from the substrate. A diffusion film is formed on the fin type active pattern. The diffusion film includes an impurity. The impurity is diffused into a lower portion of the fin type active pattern to form a punch-through stopper diffusion layer.

### CROSS-REFERENCE TO RELATED APPLICATION

This application claims priority under 35 U.S.C. §119 to Korean Patent Application No. 10-2013-0071806; filed on Jun. 21, 2013 in the Korean Intellectual Property Office, the disclosure of which is incorporated herein by reference in its entirety.

### TECHNICAL FIELD

The present inventive concept relates to a method for fabricating a semiconductor device.

### DISCUSSION OF RELATED ART

Process technology has been developed to densely integrate complementary metal oxide semiconductor (CMOS) transistors, minimizing short channel effects of CMOS transistors and securing a high-speed operation of CMOS transistors at a low operating voltage. CMOS transistors having a three dimensional structure, such as fin field effect transistors (FinFETs), have been introduced. Compared to planar transistors, FinFETs may reduce a short channel effect due to their three dimensional channel structure.

### SUMMARY

According to an exemplary embodiment of the present inventive concept, a method of fabricating a semiconductor device is provided. A fin type active pattern is formed on a substrate. The fin type active pattern projects from the substrate. A diffusion film is formed on the fin type active pattern. The diffusion film includes an impurity. The impurity is diffused into a lower portion of the fin type active pattern to form a punch-through stopper diffusion layer.

According to an exemplary embodiment of the present inventive concept, a method of fabricating a semiconductor device is provided. A fin type active pattern is formed on a substrate. The fin type active pattern projects from the substrate. A diffusion film is formed on the fin type active pattern. The diffusion film includes an impurity. The impurity is diffused into a lower portion of the fin type active pattern to form a punch-through stopper diffusion layer. A transistor is formed on the fin type active pattern. The transistor includes a source and a dram. The source and the drain are formed in an upper portion of the fin type active pattern.

According to an exemplary embodiment of the present inventive concept, a method of fabricating a semiconductor device is provided. A fin type active pattern is formed on a substrate. The fin type active pattern projects from the substrate. A diffusion film is formed on the fin type active pattern. The diffusion film includes a first impurity of a first conduction type and is in contact with a lower portion of the fin type active pattern. A punch-through stopper diffusion layer is formed by diffusing the first impurity into the lower portion of the fin type active pattern and the substrate. A source/drain of a transistor is formed in an upper portion of the fin type active pattern. The source/drain includes a second impurity of a second conduction type different from the first conduction type.

### BRIEF DESCRIPTION OF THE DRAWINGS

These and other features of the inventive concept will become more apparent by describing in detail exemplary embodiments thereof with reference to the accompanying drawings of which:

FIG. 1 is a perspective view illustrating a semiconductor device according to an exemplary embodiment of the present inventive concept;

FIG. 2 is a cross-sectional view taken along line A-A of FIG. 1;

FIG. 3 is a cross-sectional view taken along line B-B of FIG. 1;

FIG. 4 is a perspective view illustrating a semiconductor device according to an exemplary embodiment of the present inventive concept;

FIG. 5 is a cross-sectional view taken along line C-C of FIG. 4;

FIG. 6 is a perspective view illustrating a semiconductor device according to an exemplary embodiment of the present inventive concept;

FIG. 7 is a cross-sectional view taken along line D-D of FIG. 6;

FIG. 8 is a perspective view illustrating a semiconductor device according to an exemplary embodiment of the present inventive concept;

FIG. 9 is a perspective view illustrating a semiconductor device according to an exemplary embodiment of the present inventive concept;

FIG. 10 is a perspective view illustrating a semiconductor device according to an exemplary embodiment of the present inventive concept;

FIG. 11 is a cross-sectional view illustrating a semiconductor device according to an exemplary embodiment of the present inventive concept;

FIG. 12 is a perspective view of a semiconductor device according to an exemplary embodiment of the present inventive concept;

FIGS. 13A to 13H and 14 are cross-sectional views illustrating a method for s fabricating the semiconductor device of FIG. 1;

FIGS. 15A to 15D are cross-sectional views illustrating a method for fabricating the semiconductor device of FIG. 6;

FIGS. 16 to 27 are perspective views illustrating a method for fabricating the semiconductor device of FIG. 12;

FIG. 28 is a block diagram of an electronic system including a semiconductor device according to an exemplary embodiment of the present inventive concept; and

FIGS. 29 and 30 are semiconductor systems including a semiconductor device according to an exemplary embodiment of the present inventive concept.

### DETAILED DESCRIPTION OF THE EXEMPLARY EMBODIMENTS

Exemplary embodiments of the inventive concept will be described below in detail with reference to the accompanying drawings. However, the inventive concept may be embodied in different thrills and should not be construed as limited to the embodiments set forth herein. In the drawings, the thickness of layers and regions may be exaggerated for clarity. It will also be understood that when an element is referred to as being “on” another element or substrate, it may be directly on the other element or substrate, or intervening layers may also be present. It will also be understood that when an element is referred to as being “coupled to” or “connected to” another element, it may be directly coupled to or connected to the other element, or intervening elements may also be present. Like reference numerals may refer to the like elements throughout the specification and drawings.

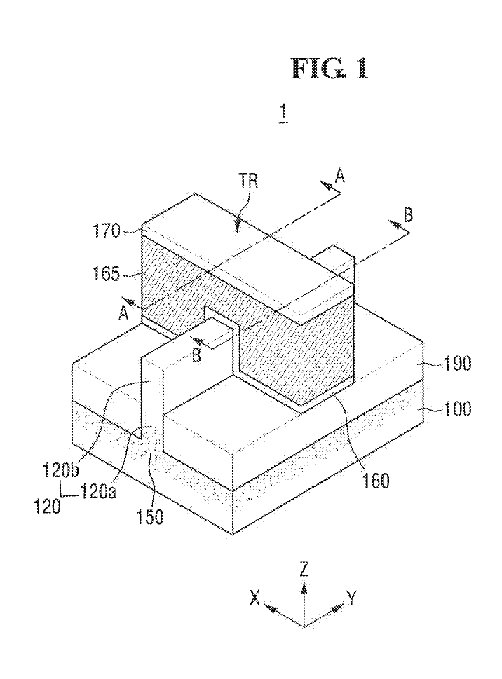

Hereinafter, referring to FIGS. 1 to 3, a semiconductor device according to an exemplary embodiment of the present inventive concept will be described.

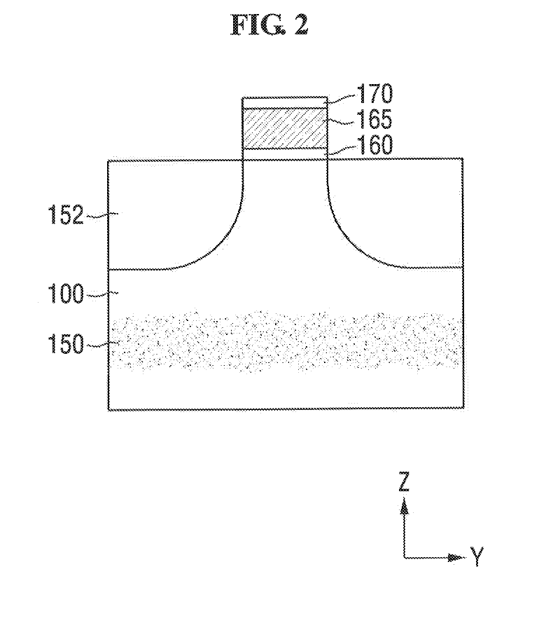

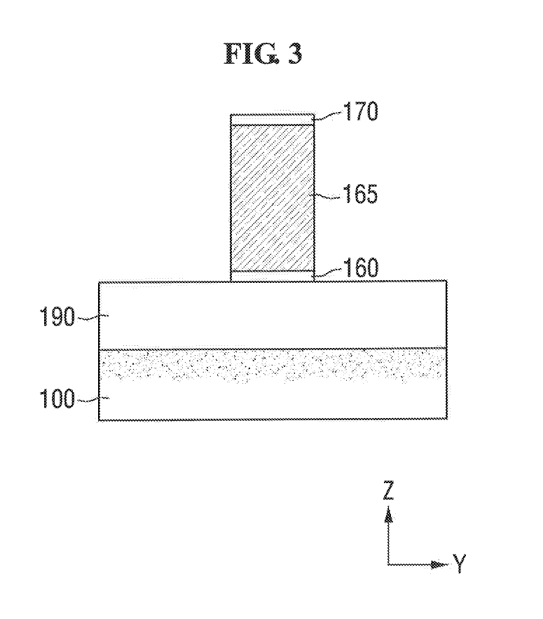

FIG. 1 is a perspective view of a semiconductor device according to an exemplary embodiment of the present inventive concept. FIG. 2 is a cross-sectional view taken along line A-A of FIG. 1, and FIG. 3 is a cross-sectional view taken along line BB of FIG. 1.

A semiconductor device 1 according to an exemplary embodiment of the present inventive concept includes a substrate 100, a fin type active pattern 120, a punch-through stopper diffusion layer 150, a first gate insulating film 160, a first gate electrode 165, a first gate mask pattern 170, and an isolation film 190.

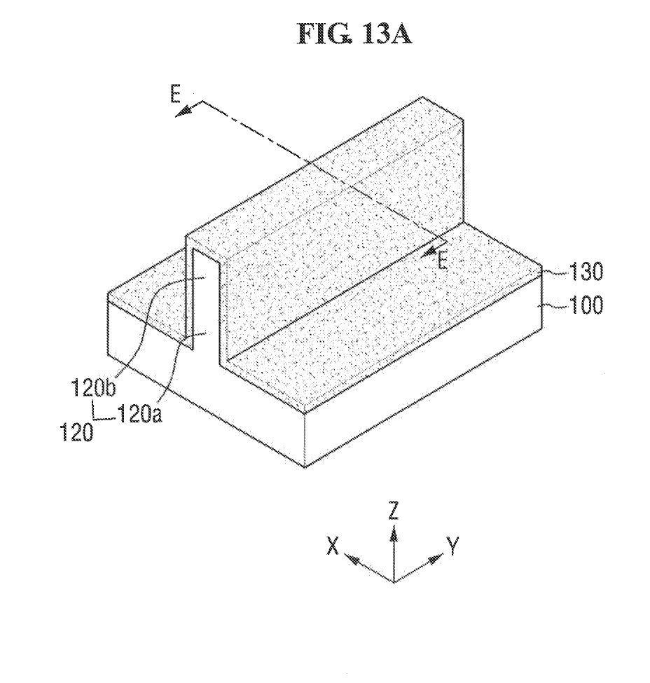

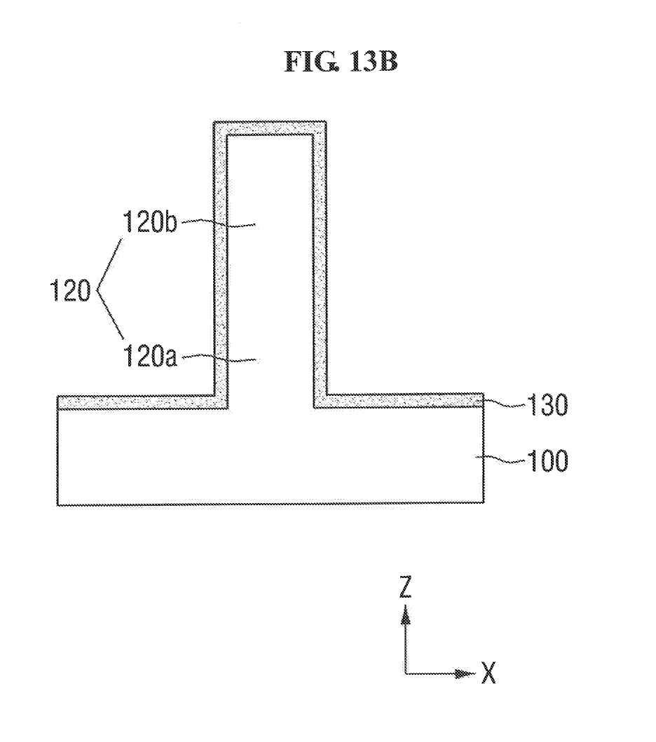

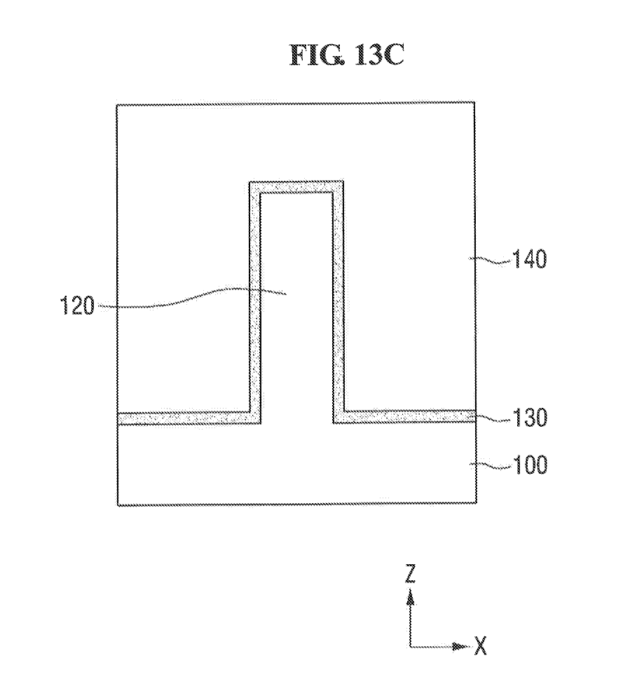

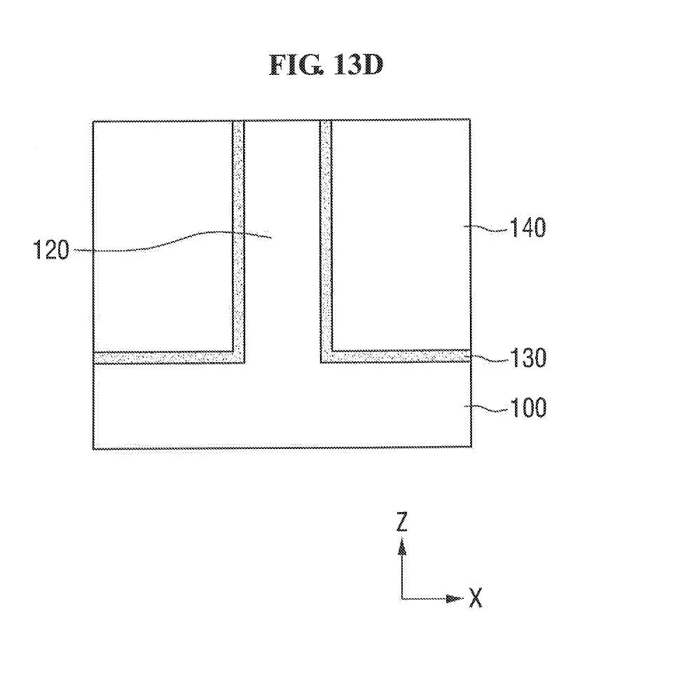

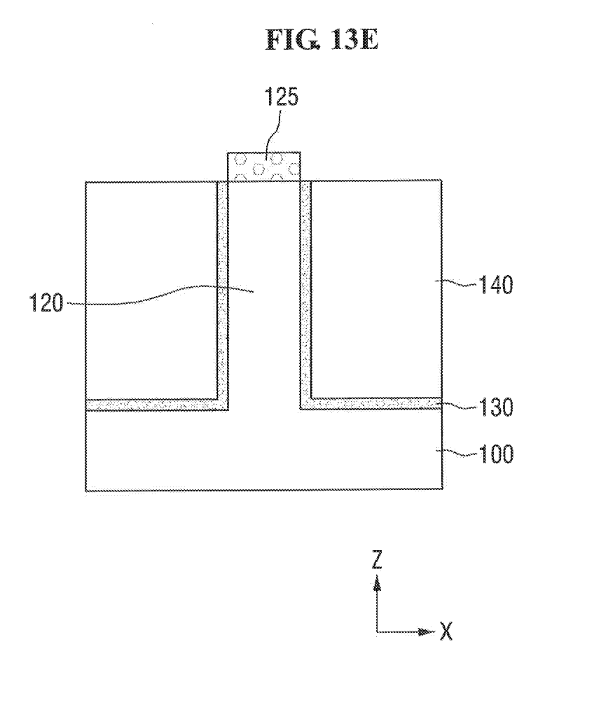

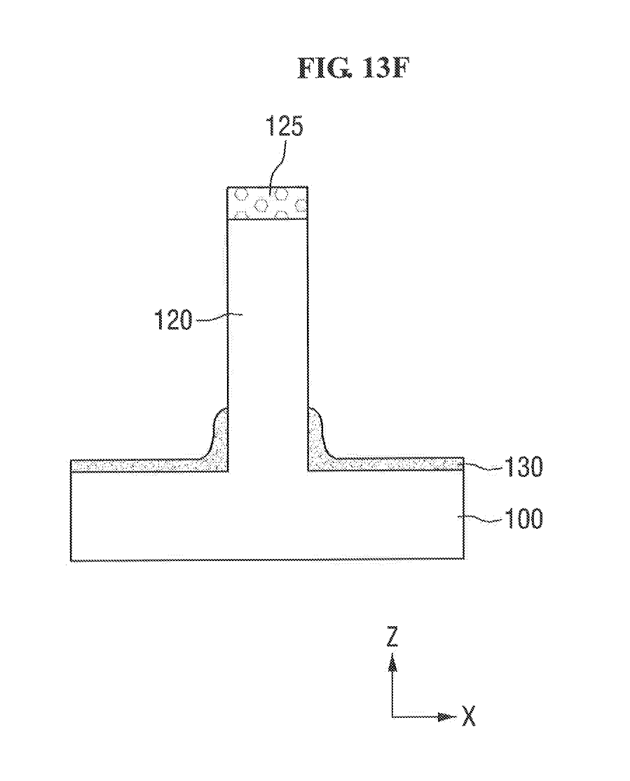

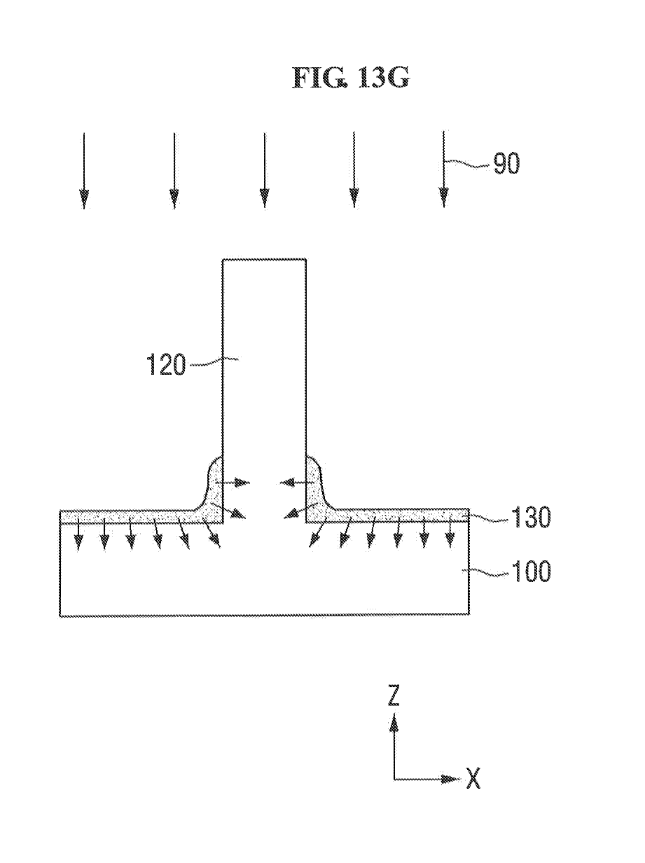

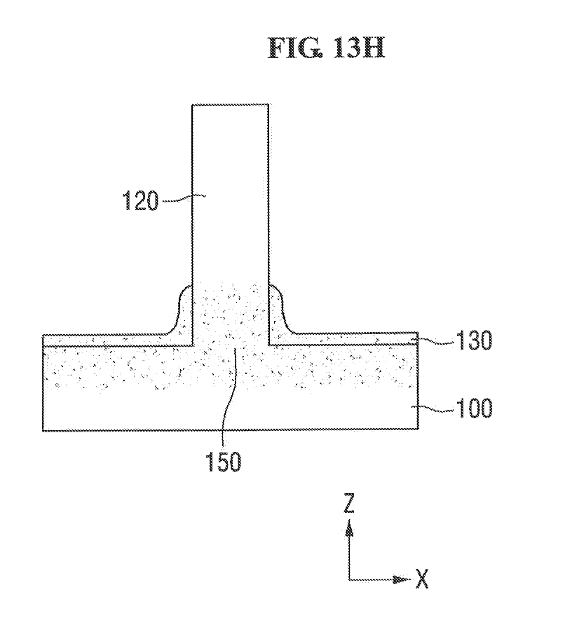

For example, the substrate 100 may be made of at least one of Si, Ge, SiGe, GaP, GaAs, SiC, SiGeC, InAs, and InP. An SOI (Silicon On Insulator) substrate may be used. The substrate 100 may be formed of an epitaxial layer formed on a base substrate. The substrate 100 may include an impurity that is diffused from a first diffusion film 130 of FIG. 13A in a process of fabricating the semiconductor device 1 to be described later. The detailed description thereof will be made later.

The fin type active pattern 120 may be formed to project from the substrate 100. For example, the fin type active pattern 120 may be formed through etching of the substrate 100. Further, the fin type active pattern 120 may include a lower portion 120a and an upper portion 120b of the fin type active pattern.

The punch-through stopper diffusion layer 150 may be formed in the lower portion 120a of the fin type active pattern. For example, the punch-through stopper diffusion layer 150 may be formed through diffusion of the impurity included in the first diffusion film 130 of FIG. 13A.

The punch-through stopper diffusion layer 150 may be used to prevent leakage due to punch-through. For example, the punch-through stopper diffusion layer 150 may be used to prevent a loss of the function of the semiconductor device due to the leakage to form the semiconductor device having high reliability.

The punch-through stopper diffusion layer 150 may include an impurity having a conduction type that is different from the conduction type of a transistor TR formed on the fin type active pattern 120. For example, if the semiconductor device I N-type field effect transistor (nFET), the punch-through stopper diffusion layer 150 may include a p-type impurity such as boron (B). If the semiconductor device 1 is a p-type FET (pFET), the punch-through stopper diffusion layer 150 may include an n-type impurity such as phosphorous (P) or arsenic (As).

The first gate insulating film 160, the first gate electrode 165, and the first gate mask pattern 170 may be sequentially formed on the isolation film 190 and the fin type active pattern 120. For example, by performing an etching process using the first gate mask pattern 170, the first gate insulating film 160 and the first gate electrode 165, which extend in a first direction X to cross the fin type active pattern 120, may be formed.

For example, the first gate insulating film 160 may include a silicon oxide film. Alternatively, the first gate insulating film 160 my include a high-k dielectric material having a dielectric constant greater than the dielectric constant of the silicon oxide film. The first gate electrode 165 may include poly silicon and/or metal, but are not limited thereto.

The transistor TR of the semiconductor device 1 according to an exemplary embodiment of the present inventive concept may include a gate-first structure. In the gate-first structure, a first source/drain 152 may be formed on the fin type active pattern 120 after a gate is formed. The first source/drain 152 may he formed in the upper portion 120b of the fin type active pattern. For example, the first source/drain 152 may be formed in the upper portion 120b of the fin type active pattern, and the punch-through stopper diffusion layer 150 may be formed in the lower portion 120a of the fin type active pattern. As shown in FIG. 2, the first source/drain 152 may be spaced apart from the punch-through stopper diffusion layer 150. Further, the first source/drain 152 may be formed by an epitaxial process, and during the epitaxial process, an impurity may be doped in-situ.

For a pFET, the first source/drain 152 may include a compression stress material. For example, the compression stress material may be a material having higher lattice constant than the lattice constant of Si. The compression stress material may include, for example, SiGe. The compression stress material may improve mobility of carriers of a channel region through application of compression stress to the fin type active pattern.

For an nFET, the first source/drain 152 may be made of the same material as the material of the substrate 100 or a tensile stress material. For example, if the substrate 100 is made of Si, the first source/drain 152 may be made of Si or a material having lower lattice constant than the lattice constant of Si. The tensile stress material may include SiC.

Further, the material of the first source/drain 152 may differ depending on whether the semiconductor device is a pFET or an n FET.

The isolation film 190 that is composed of an insulator may be formed on the substrate 100. For example, the isolation film 190 may be formed by forming the insulator on the substrate 100 to cover an upper portion 120b of the fin type active pattern 120 and then recessing an upper portion of the insulator until the upper portion of the fin type active pattern 120 is exposed. In this case, a selective etching process may be used as the recess process for forming the isolation film 190.

The isolation film 190 may be formed of a material that includes at least one of silicon oxide, silicon nitride, and silicon oxynitride, but the present inventive concept is not limited thereto.

The semiconductor device 1 according to an exemplary embodiment of the present inventive concept may include the punch-through stopper diffusion layer 150 to prevent punch-through between source/drains 152 from occurring in the lower portion 120a of the fin type active pattern 120 of the FinFET semiconductor device 1. The punch-through stopper diffusion layer 150 may be uniformly formed in the lower portion of the fin type active pattern 120. By preventing the punch-through, the semiconductor to device having high reliability may be provided.

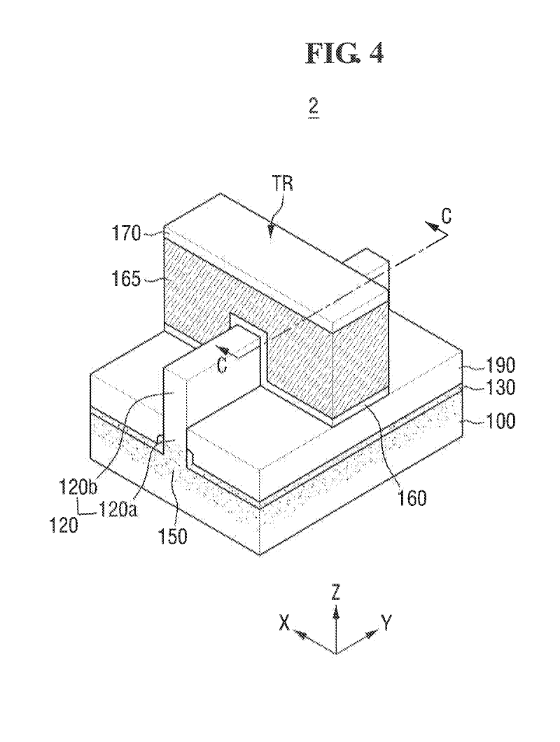

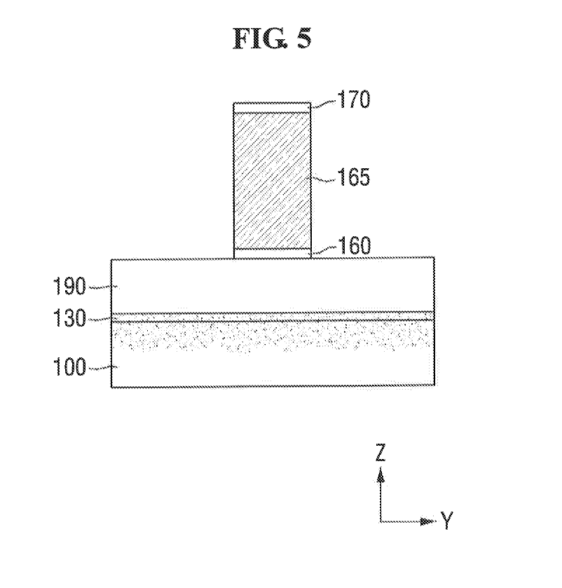

FIG. 4 is a perspective view illustrating a semiconductor device according to an exemplary embodiment of the present inventive concept, and FIG. 5 is a cross-sectional view taken along line C-C of FIG. 4. Hereinafter, explanation will be made about differences between the semiconductor devices according to this exemplary embodiment and the above-described embodiment.

Referring to FIGS. 4 and 5, a semiconductor device 2 according to an exemplary embodiment of the present inventive concept further includes a first diffusion film 130.

The first diffusion film 130 may be formed on the fin type active pattern 120 and the substrate 110. For example, the first diffusion film 130 may cover the lower portion 120a of the fin type active pattern without covering the upper portion 120b of the fin type active pattern 120.

The first diffusion film 130 may include an impurity having a conduction type that is different from the conduction type of the semiconductor device 2. For example, if the semiconductor device 2 includes an nFET, the first diffusion film 130 may include a p-type impurity such as boron (B). If the semiconductor device 2 includes a pFET, the first diffusion film 130 may include an n-type impurity such as phosphorous (P) or arsenic (As). The impurity that is included in the first diffusion film 130 may be diffused into the lower potion 120a of the fin type active pattern and the substrate 100 through, for example, heat treatment 90 of FIG. 13G. The detailed explanation thereof will be made later.

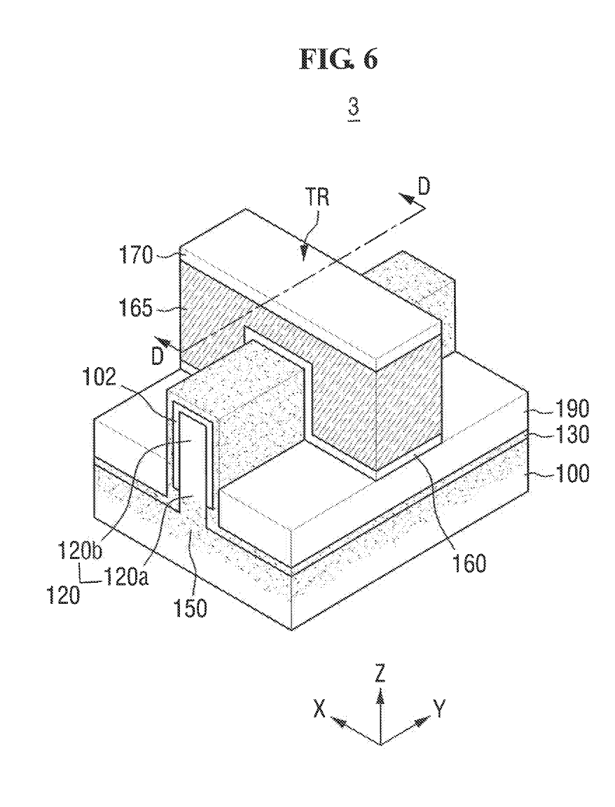

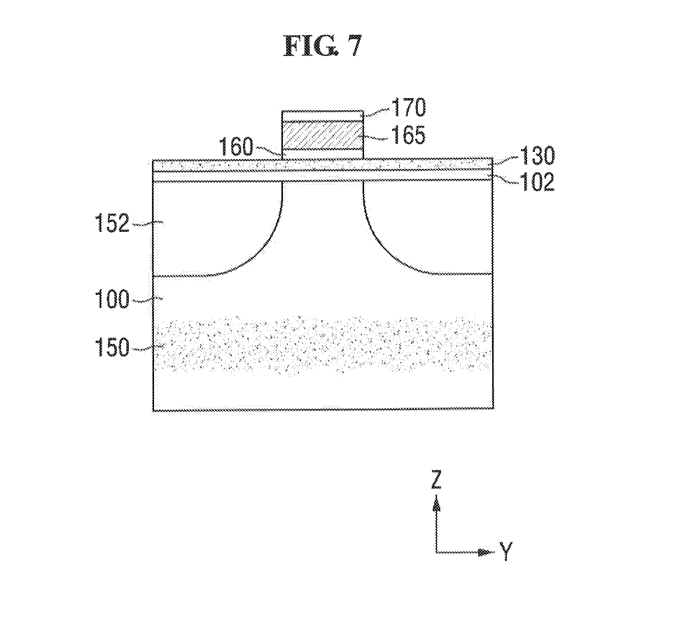

FIG. 6 is a perspective view illustrating a semiconductor device according to an exemplary embodiment of the present inventive concept, and FIG. 7 is a cross-sectional view taken along line D-D of FIG. 6. Hereinafter, descriptions will be made about differences between the semiconductor devices according to this exemplary embodiment and the above-described exemplary embodiment.

Referring to FIG. 6, a semiconductor device 3 according to an exemplary embodiment of the present inventive concept further includes an insulating film 102. In this case, the insulating film 102 may cover the upper portion 120b of the fin type active pattern. By covering the upper portion 120b of the fin type active pattern, the insulating film 102 may prevent an impurity that is included in the first diffusion film 130 from being diffused into the upper portion 120b of the fin type active pattern. The insulating film 102 may include, for example, a nitride film, but is not limited thereto.

The first diffusion film 130 may cover the lower portion 120a of the fin type active pattern and the insulating film 102. For example, the first diffusion film 130 may cover the whole surface of the fin type active pattern 120.

The insulating film 102 may cover the upper portion 120b of the fin type active pattern, and thus may prevent the impurity of the first diffusion film 130 from being diffused into the upper portion 120h of the fin type active pattern.

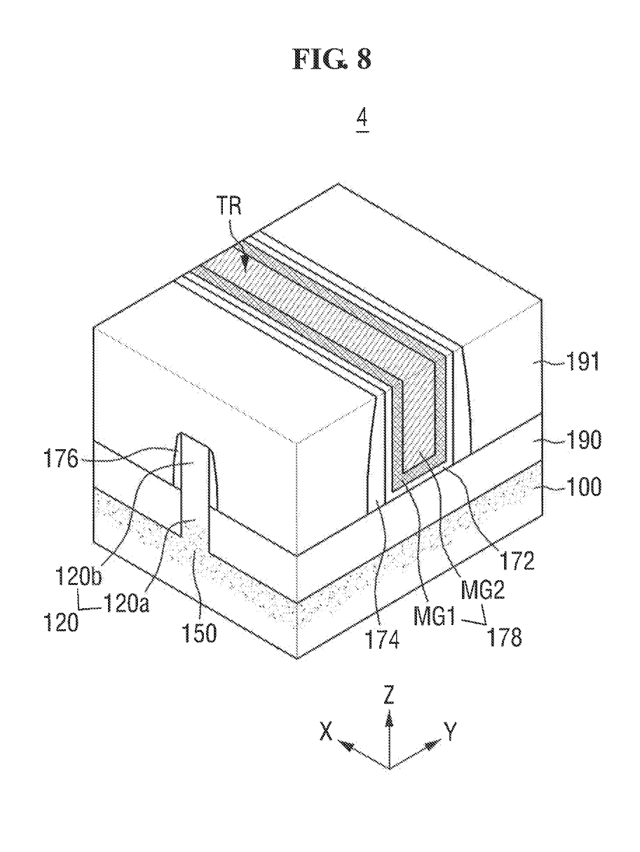

FIG. 8 is a perspective view illustrating a semiconductor device according to an exemplary embodiment of the present inventive concept FIG. 8 illustrates a gate-last structure of the semiconductor device of FIG. 1.

Referring to FIG. 8, a semiconductor device 4 may include a second gate insulating film 172 and a second gate electrode 178. The second gate electrode 178 may include a first metal layer MG1 and a second metal layer MG2. The first metal layer MG1 may be formed to extend in a second direction. Z along a side wall of a first spacer 174, in the gate-last process, the second gate insulting film 172 and the first metal layer MG1 may be included in the second gate electrode 178 as described in FIG. 8. The fabricating process of the gate-last process will be described later.

The first spacer 174 may be formed on both side walls of the second gate insulating film 172, and a second spacer 176 may be formed on both side wails of the fin type active pattern 120. The first spacer 174 and the second spacer 176 may include, for example, a silicon nitride film or a silicon oxynitride film, but are not limited thereto. MOM The second gate insulating film 172 and the second gate electrode 178 maybe sequentially formed between the first spacers 174.

For example, the second gate electrode 178 may include the first and the second metal layer MG1 and MG2. For example, the second gate electrode 178 may be formed through lamination of two or more metal layers MG1 and MG2. The first metal layer MG1 serves to adjust a work function, and the second metal layer MG2 serves to fill a space formed by the first metal layer MG1 between the first spacers 174. The first metal layer MG1 may include, for example, at least one of TiN, TaN, TiC, and TaC. The second metal layer MG2 may include, for example. W or Al. Alternatively, the second gate electrode 178 may be made of Si or SiGe.

A second interlayer insulating film 191 may be formed on a resultant material on which the first spacer 174 and the second spacer 176 are formed. For example, after the source and the drain 152 (in FIG. 2) are formed on the fin type active pattern 120, the second interlayer insulating film 191 may be formed. After the second interlayer to insulating film 191 is formed, the second gate insulating film 172 and the second gate electrode 178 may be sequentially formed between the first spacers 174.

The second interlayer insulating film 191 may include, for example, silicon oxide, but is not limited thereto.

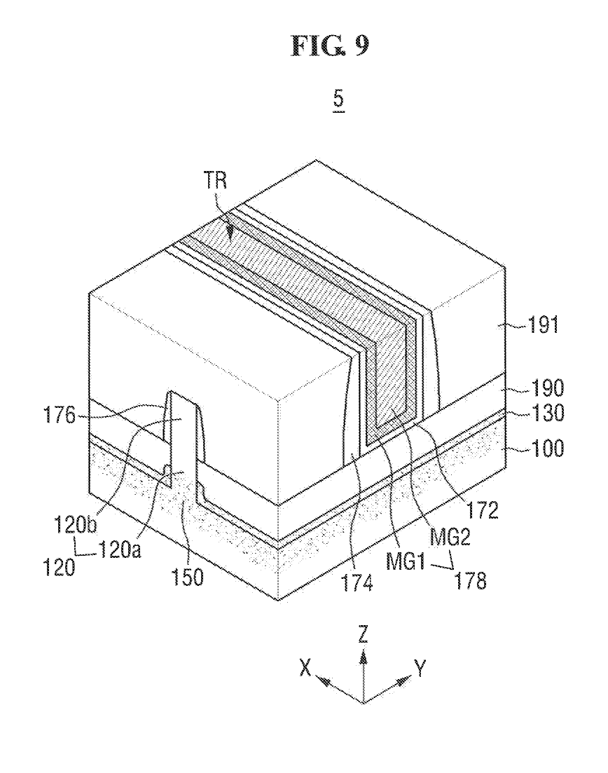

FIG. 9 is a perspective view illustrating a semiconductor device according an is exemplary embodiment of the present inventive concept. FIG. 9 illustrates a gate-last structure of the semiconductor device of FIG. 4.

Hereinafter, descriptions will be made about differences between the semiconductor devices according to this exemplary embodiment and the above-described exemplary embodiment of FIG. 8.

Referring to FIG. 9, a semiconductor device 5 according to an exemplary embodiment of the present inventive concept further includes a first diffusion film 130.

For example, the first diffusion film 130 may be formed on the fin type active pattern 120 and the substrate 100. For example, the first diffusion film 130 may cover the lower portion 120a of the fin type active pattern 120 without covering the upper portion 120b of the fin type active pattern 120.

The first diffusion film 130 may include an impurity having a conduction type that is different from the conduction type of the semiconductor device 5. For example, if the semiconductor device 5 includes an nFET, the first diffusion film 130 may include a p-type impurity such as boron (B). If the semiconductor device 5 includes a pFET, the first diffusion film 130 may include an n-type impurity such as phosphorous (P) or arsenic (As). The impurity that is included in the first diffusion film 130 may be diffused into the lower potion 120a of the fin type active pattern and the substrate 100 through, for example, heat treatment 90 of FIG. 13G.

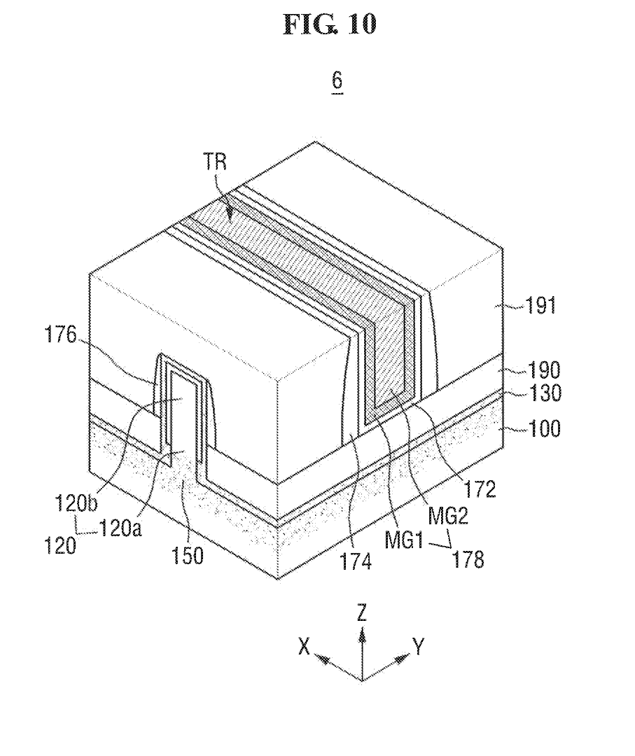

FIG. 10 is a perspective view illustrating a semiconductor device according to an exemplary embodiment of the present inventive concept. FIG. 10 illustrates a gate-last structure of the semiconductor device of FIG. 6.

Hereinafter, descriptions will be made about differences between the semiconductor devices according to this exemplary embodiment and the above-described exemplary embodiments of FIG. 8 or FIG. 9.

Referring to FIG. 10, a semiconductor device 6 according to an exemplary embodiment of the present inventive concept further includes an insulating film 102.

In this case, the insulating film 102 may cover the upper portion 120b of the fin type active pattern. By covering the upper portion 120b of the fin type active pattern, the insulating film 102 may prevent an impurity that is included in the first diffusion film 130 from being diffused into the upper portion 120b of the fin type active pattern. The insulating film 102 may include, for example, a nitride film, but is not limited thereto.

The first diffusion film 130 may cover the lower portion 120a of the fin type active pattern and the insulating film 102. The first diffusion film 130 may cover the is whole surface of the fin type active pattern 120.

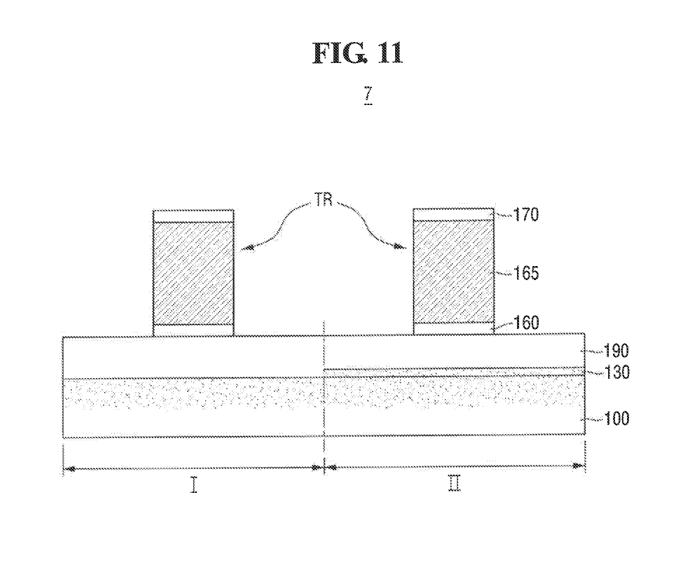

FIG. 11 is a cross-sectional view illustrating a semiconductor device according to an exemplary embodiment of the present inventive concept.

Referring to FIG. 11, a substrate 100 of a semiconductor device 7 may include a first region (I region) and a second region (II region).

The semiconductor device 7 may include a Complementary Metal Oxide Semiconductor (CMOS) transistor. For example, the first region (I region) of the substrate 100 may include any one of a P-type Metal Oxide Semiconductor (PMOS) transistor and an N-type Metal Oxide Semiconductor (NMOS) transistor, and the second region (II region) of the substrate 100 may include the other of the PMOS transistor and the NMOS transistor.

For example, the first region (I region) of the substrate 100 may include the semiconductor device of FIG. 1, and the second region (II region) of the substrate 100 may include the semiconductor device of FIG. 4. In this case, the impurity included in the first diffusion film 130 may be of a conduction type that is different from the conduction type of the transistor.

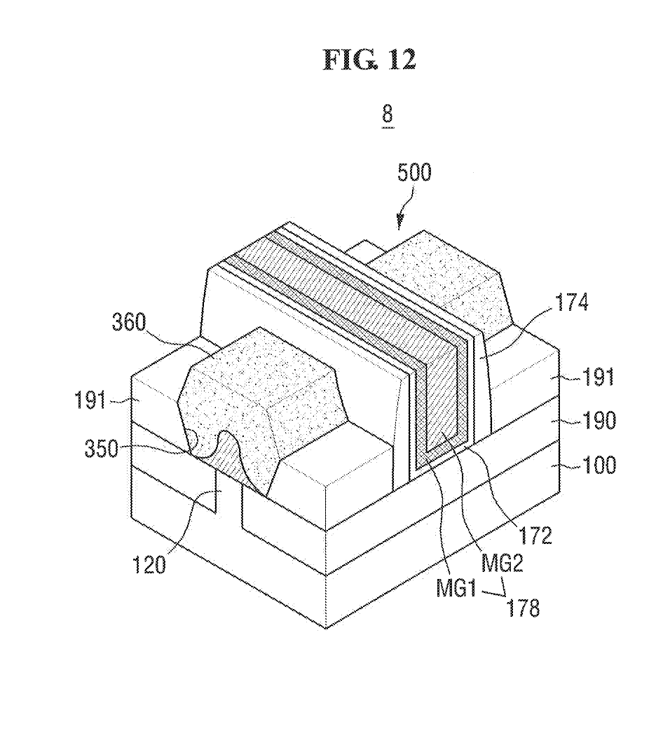

FIG. 12 is a perspective view of a semiconductor device according to an exemplary embodiment of the present inventive concept.

Referring to FIG. 12, a semiconductor device 8 according to an exemplary embodiment of the present inventive concept includes a substrate 100, a fin type active pattern 120, a first spacer 174, a second gate insulating film 172, a second gate electrode 178, an isolation film 190, a second interlayer insulating film 191, a recess 350, and a second source/drain 360.

The substrate 100 may be made of at least one of Si, Ge, SiGe, GaP, GaAs, SiC, SiGeC, InAs, and InP. An SOI (Silicon On Insulator) substrate may be used. The substrate 100 may be formed of an epitaxial layer on a base substrate.

The fin type active pattern 120 may be formed to project from the substrate 100. For example, the fin type active pattern 120 may be formed through etching of the substrate 100.

The first spacer 174 may be formed on both side walls of the second gate insulating film 172.

The first spacer 174 may include, for example, a silicon nitride film or a silicon oxynitride film, but is not limited thereto.

The second gate insulating film 172 and the second gate electrode 178 may be is formed between the first spacers 174.

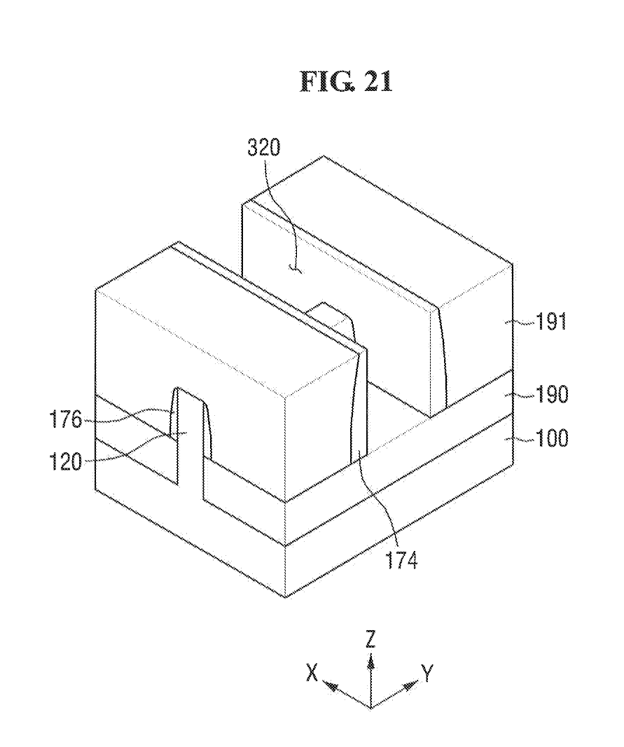

The second gate insulating film 172 may include a high-k dielectric material having a dielectric constant greater than the dielectric constant of the silicon oxide film. For example, the second gate insulating film 172 may include HfO2, ZrO2, or Ta2O5. The second gate insulating film 172 may be substantially conformally formed along a side wall and a lower surface of a trench 320 of FIG. 21.

The second gate electrode 178 may include metal layers MG1 and MG2. The second gate insulating film 172 and the first metal layer MG1 included in the second gate electrode 178 may be formed to extend in the second direction Z along the side wall of the first spacer 174. The first metal layer MG1 serves to adjust a work function, and the second metal layer MG2 serves to fill a space formed by the first metal layer MG1. For example, the first metal layer MG1 may include, for example, at least one of TiN, TaN, TiC, and TaC. Further, the second metal layer MG2 may include, for example, W or Al. Alternatively, the second gate electrode 178 may be made of Si or SiGe.

The isolation film 190 may be formed on the substrate 100. The isolation film 190 may be formed of a material that includes at least one of silicon oxide, silicon nitride, and silicon oxynitride, but the present inventive concept is not limited thereto.

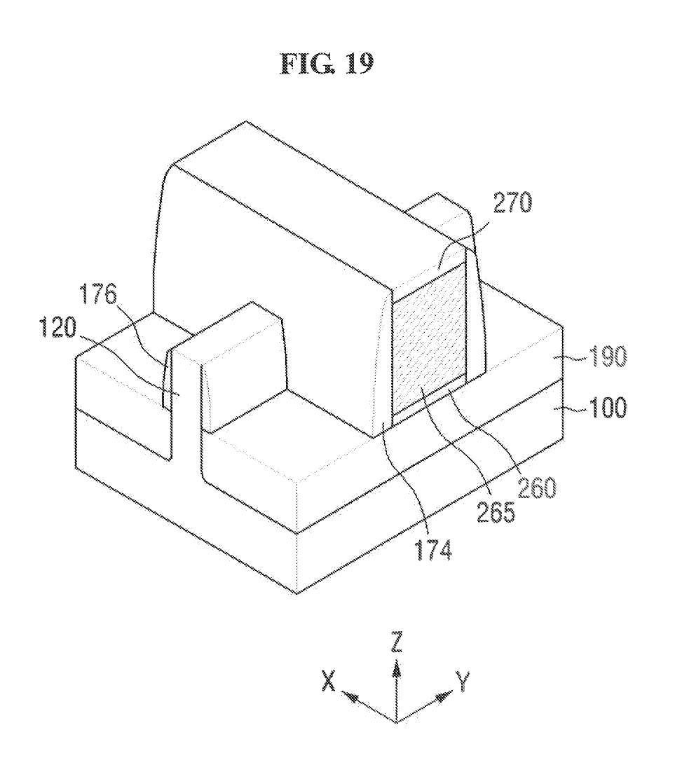

The second interlayer insulating film 191 may be formed on the first spacer 174 and the second spacer 176 of FIG. 19. The second interlayer insulating film 191 may include silicon oxide, but is not limited thereto.

The recess 350 may be formed in the fin type active pattern 120 on both sides of the second gate electrode 178. The side wall of the recess 350 is inclined, and the shape of the recess 350 becomes wider as it goes far from the substrate 100. The width of the recess 350 may be wider than the width of the fin type active pattern 120.

The second source/drain 360 may be formed within the recess 350. For example, the second source/drain 360 may be in an elevated source/drain shape. For example, the upper surface of the second source/drain 360 may be higher than the upper surface of the second interlayer insulating film 191.

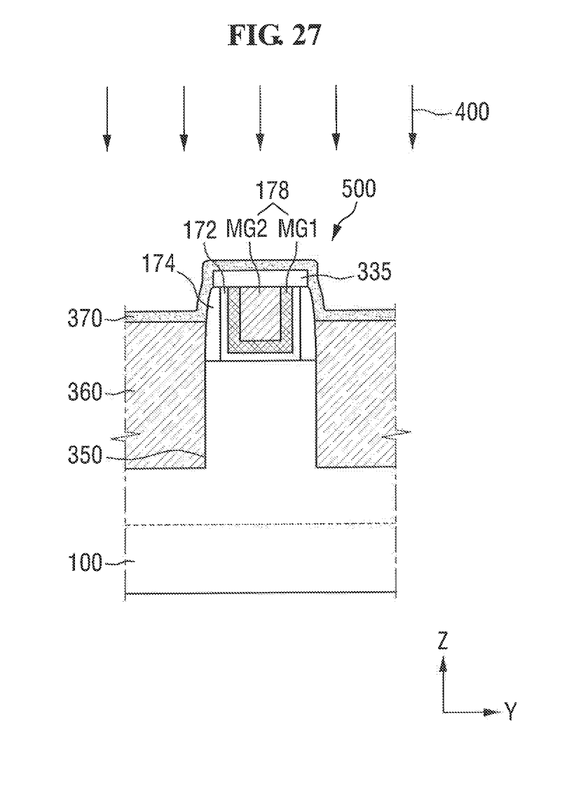

The second source/drain 360 may include an impurity that is diffused from the second diffusion film 370 of FIG. 27. FIG. 12 illustrates the second source/drain 360 into which the impurity has been diffused and spread.

The impurity may serve to reduce resistance of the second source/drain 360 that is increased due to a compression stress or tensile stress material.

Since the semiconductor device 8 according to an exemplary embodiment of the present inventive concept is formed using the impurity diffusion rather than ion injection, the roughness increase and damage of the source/drain surface may be prevented, and the merging of two neighboring transistors may be prevented.

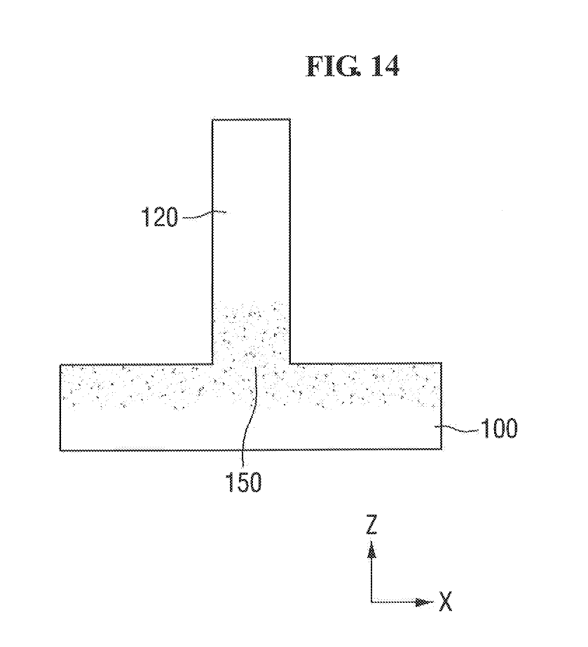

FIG. 13A is a perspective view illustrating a method for fabricating the semiconductor device of FIG. 1. FIGS. 13B to 13H and 14 are cross-sectional views taken along line EE of FIG. 13A.

Referring to FIGS. 13A and 13B, a first diffusion film 130 is formed on a substrate 100 and a fin type active pattern 120. For example, the first diffusion film 130 may be formed to cover an upper surface of the substrate 100 and an upper surface and a side surface of the fin type active pattern 120.

The first diffusion film 130 may include an impurity having a conduction type that is different from the conduction type of a transistor formed on the fin type active pattern 120. For example, if the transistor includes an nFET, the first diffusion film 130 may include a p-type impurity such as boron (B), while if the transistor includes a pFET, the first diffusion film 130 may include an n-type impurity such as phosphorous (P) or arsenic (As).

Referring to FIG. 13C, a first interlayer insulating film 140 is formed on the first diffusion film 130. As illustrated, the first interlayer insulating film 140 may be formed to entirely cover the fin type active pattern 120 and the first diffusion film 130. Accordingly, an upper surface of the fin type active pattern 120 and an upper surface of the first diffusion film 130 may be covered by the first interlayer insulating film 140. Here, the first interlayer insulating film 140 may include, for example, an oxide film or a nitride film, but is not limited thereto.

Referring to FIG. 13D, the first interlayer insulating film 140 and the first s diffusion film 130 may be planarized until the upper surface of the fin type active pattern 120 is exposed. The planarization process may include, for example, a Chemical-Mechanical Planarization (CMP) process, but is not limited thereto.

Referring to FIGS. 13E and 13F, after the planarization process, a first mask pattern 125 is formed on the fin type active pattern 120. Then, using the first mask pattern 125 as a mask, the first diffusion film 130 may be etched. For example, using an etching selectivity between the first interlayer insulating film 140 and the first diffusion film 130, the first diffusion film 130 may be selectively etched. The etching process may include a wet etching process.

After the first diffusion film 130 is etched, the first interlayer insulating film is 140 may be removed. The removal of the first interlayer insulating film 140 may include an etching process.

The etched first diffusion film 130 may expose the upper portion of the fin type active pattern 120 and may cover the lower portion of the fin type active pattern 120.

Referring to FIG. 13G, the impurity included in the first diffusion film 130 may be diffused into the fin type active pattern 120. For example, the impurity included in the first diffusion film 130 that is formed adjacent to the lower portion of the fin type active pattern 120 may be diffused into the lower portion of the fin type active pattern 120.

Here, the diffusion of the impurity may be performed through heat treatment 90. By performing the heat treatment 90 with respect to the first diffusion film 130, the impurity of the first diffusion film 130 may be diffused into the lower portion of the fin type active pattern 120 and the substrate 100.

Referring to FIG. 13H, the impurity that is diffused into the lower portion of the fin type active pattern 120 may form a punch-through stopper diffusion layer 150 in the lower portion of the fin type active pattern 120. The punch-through stopper diffusion layer 150 may prevent leakage due to the punch-through that occurs on the lower portion of the fin type active pattern 120.

After the punch-through stopper diffusion layer 150 is formed, as in the semiconductor device 2 illustrated in FIG. 4, the isolation film 190, the first gate insulating film 160, the first gate electrode 165, and the first gate mask pattern 170 may be sequentially formed on the first diffusion film 130 and the fin type active pattern 120.

Referring to FIG. 14, after the punch-through stopper diffusion layer 150 is formed, the first diffusion film 130 that remains on the substrate 100 may be removed.

For example, by sequentially forming the isolation film 190, the first gate insulating film 160, the first gate electrode 165, and the first gate mask pattern 170 on the substrate 100 and the fin type active pattern 120 after removing the first diffusion film 130, the semiconductor device 1 of FIG. 1 may be fabricated.

Alternatively, the semiconductor device 2 of FIG. 4 may be formed by performing a subsequent process without removing the first diffusion film 130 of FIG. 13H. For example, since the process illustrated in FIG. 14 is not performed, the semiconductor device 2 of FIG. 4 may be fabricated.

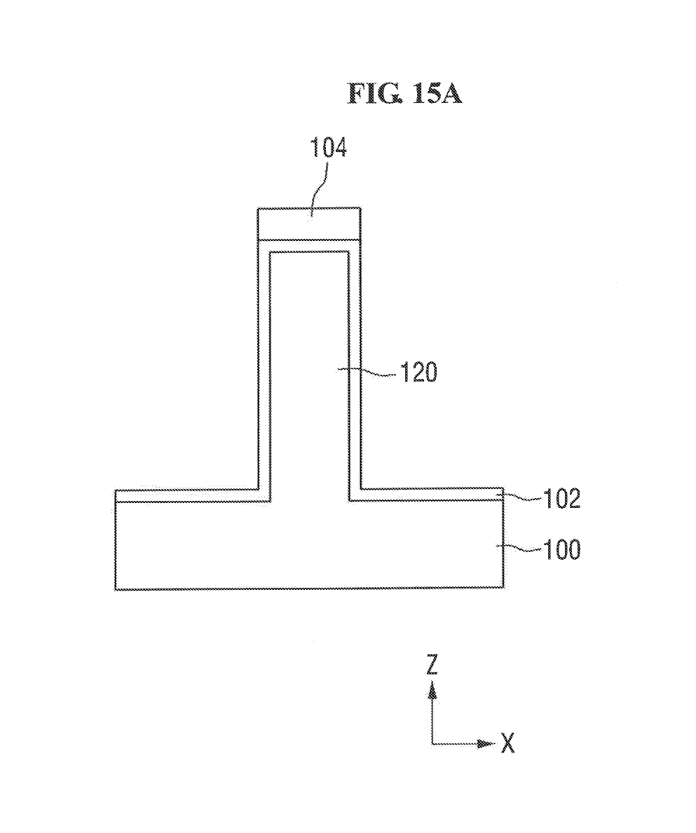

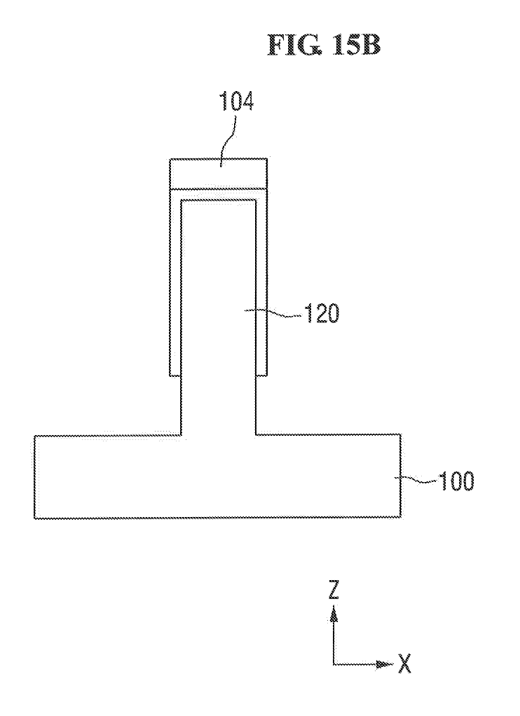

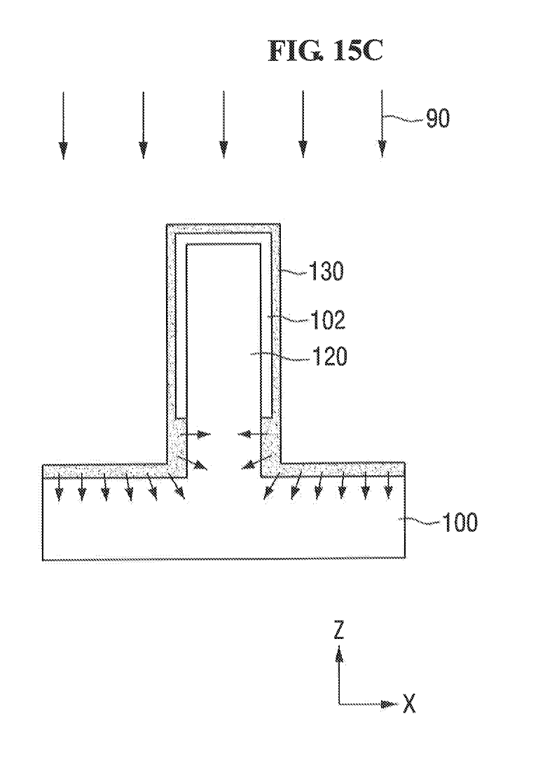

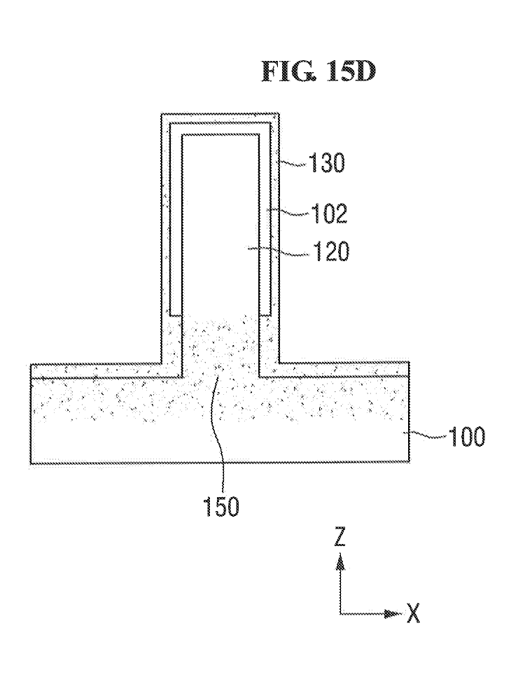

FIGS. 15A to 15D are cross-sectional views of illustrating a method for fabricating the semiconductor device of FIG. 6. Referring to FIGS. 15A to 15D, descriptions will be made about differences between the methods for fabricating the is semiconductor device according to this exemplary embodiment and the above-described exemplary embodiment of FIGS. 13A to 14.

Referring to FIG. 15A, after an insulating film 102 that covers a fin type active pattern 120 is formed, a second mask pattern 104 is formed on the insulating film 102. For example, the insulating film 102 may be formed to entirely cover the substrate 100 and the fin type active pattern 120, and the second mask pattern 104 may be formed to overlap the fin type active pattern 120. The insulating film 102 may include, for example, a nitride film, but is not limited thereto.

Referring to FIG. 15B, the insulating film 102 may be etched using the second mask pattern 104 as a mask. For example, the process of etching the insulating film 102 may include a wet etching process. Using the etching process, the insulating film 102 which covers the upper portion of the fin type active pattern 120 and exposes the lower portion of the fin type active pattern 120 may be formed.

Referring to FIG. 15C, a first diffusion film 130 may be formed on the insulating film 102. For example, the first diffusion film 130 may cover the lower portion of the fin type active pattern 120 and the insulating film 102.

The first diffusion film 130 may include, for example, an impurity having a conduction type that is different from the conduction type of a transistor formed on the fin type active pattern 120. For example, if the transistor includes an nFET, the first diffusion film 130 may include boron (B) that is a p-type impurity, while if the transistor includes a pFET, the first diffusion film 130 may include phosphorous (P) or arsenic (As) that is an n-type impurity.

After the first diffusion film 130 is formed, the impurity included in the first diffusion film 130 may be diffused into the lower portion of the fin type active pattern 120. The impurity diffusion may be performed, for example, through the heat treatment 90. By performing the heat treatment 90 with respect to the first diffusion film 130, the impurity of the first diffusion film 130 may be diffused into the lower portion of the fin type active pattern 120 and the substrate 100.

Referring to FIG. 15D, the impurity that is diffused into the lower portion of the fin type active pattern 120 may form a punch-through stopper diffusion layer 150 on the lower portion of the fin type active pattern 120. The punch-through stopper diffusion layer 150 may prevent leakage due to the punch-through that occurs on the lower portion of the fin type active pattern 120.

After the punch-through stopper diffusion layer 150 is formed, as in the semiconductor device 3 illustrated in FIG. 6, the isolation film 190, the first gate insulating film 160, the first gate electrode 165, and the first gate mask pattern 170 may be sequentially formed on the first diffusion film 130 to fabricate the semiconductor device 3 illustrated in FIG. 6.

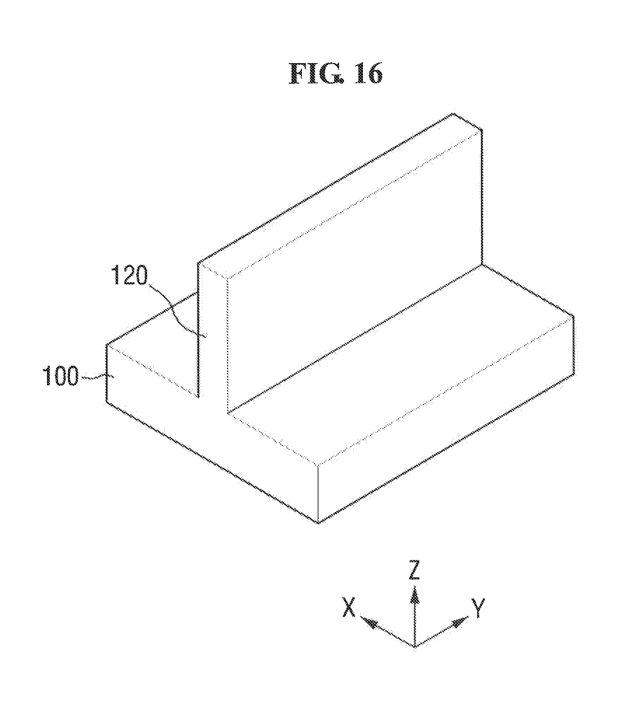

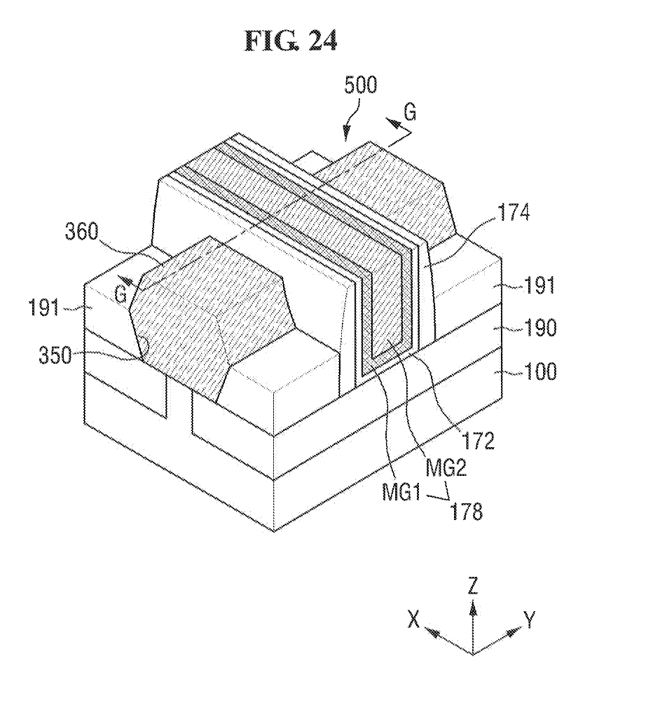

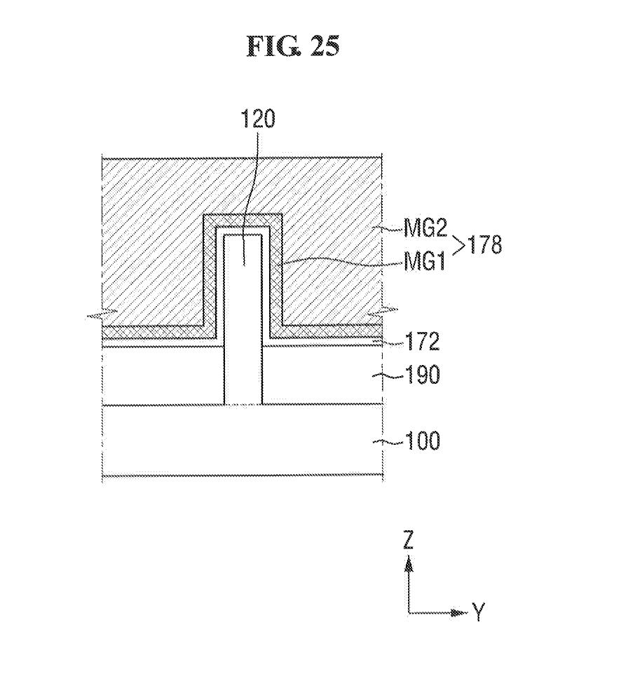

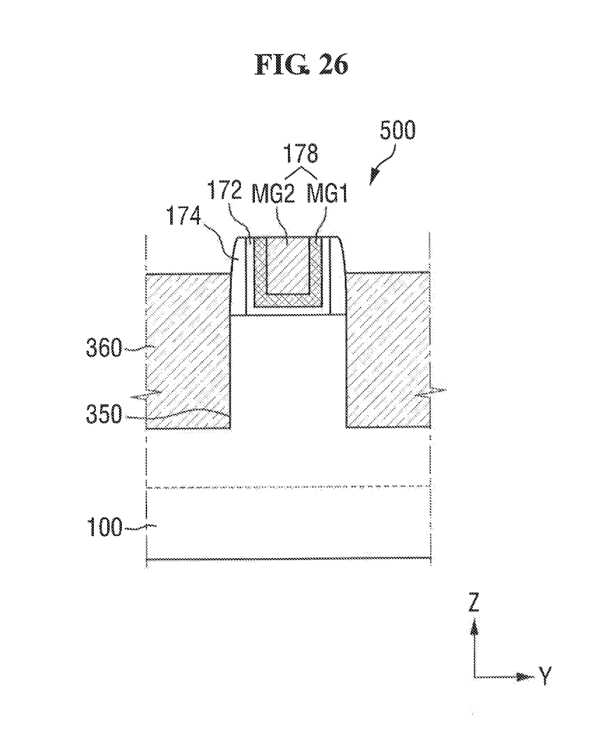

FIGS. 16 to 27 are perspective views illustrating a method for fabricating the semiconductor device of FIG. 12, FIG. 25 is a cross-sectional view taken along line F-F of FIG. 24, and FIG. 26 is a cross-sectional view taken along line G-G of FIG. 24.

Referring to FIG. 16, a fin type active pattern 120 is first formed to project from a substrate 100. Both sides of the fin type active pattern 120 may include a trench structure. For the convenience of a description, a single fin type active pattern 120 is illustrated, but the inventive concept is not limited thereto. When at least two fin type active patterns 120 are thrilled, a trench structure may be formed therebetween.

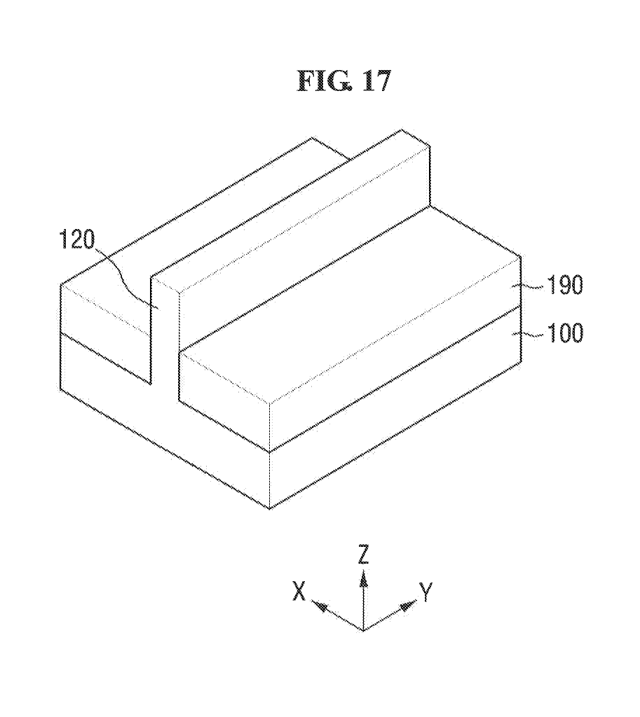

Referring to FIG. 17, an isolation film 190 is formed on the substrate 100. The isolation film 190 fills the trench structure.

The isolation film 190 may be formed of, for example, at least one of silicon oxide, silicon nitride, and silicon oxynitride, but is not limited thereto.

After the isolation film 190 is formed, an upper portion of the fin type active pattern 120 is exposed by recessing an upper portion of the isolation film 190. The recess process may include a selective etching process.

Alternatively, a part of the fin type active pattern 120 that projects from the isolation film 190 may be formed using an epitaxial process. For example, after the isolation film 190 is formed, a part of the tin type active pattern 120 may be formed using an epitaxial process. In the epitaxial process, the upper surface of the fin type active pattern 120 exposed by the isolation film 190 may serve as a seed. In this case, the s fin type active pattern 120 may be formed without using the recess process.

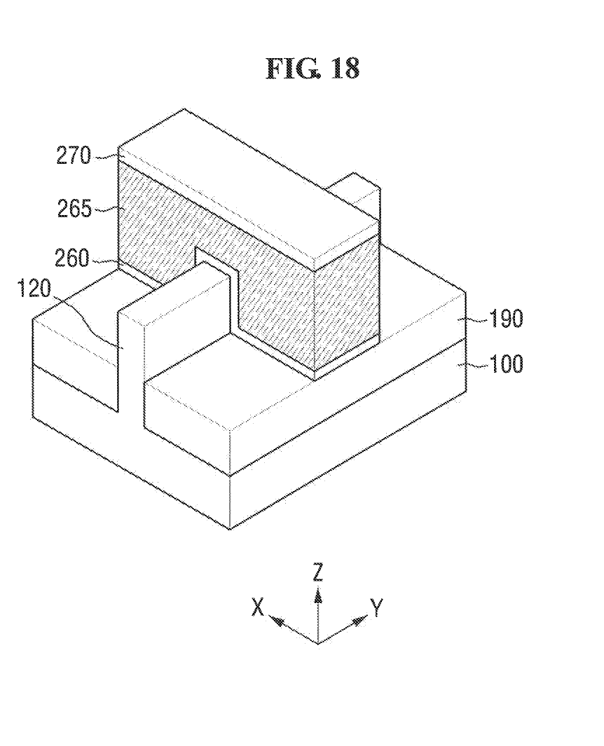

Referring to FIG. 18, a dummy gate insulating film 260 and a dummy gate electrode 265, which extend in the first direction X to cross the fin type active pattern 120, are formed using an etching process. A second gate mask pattern 270 may serve as an etch mask in the etching process.

For example, the dummy gate insulating film 260 may include silicon oxide, and the dummy gate electrode 265 may include poly silicon, but the present inventive concept is not limited thereto.

Referring to FIG. 19, a first spacer 174 and a second spacer 176 are thrilled on a side wall of the dummy gate electrode 265 and a side wall of the fin type active pattern 120.

For example, after an insulating film is formed on the dummy gate electrode 265, the first spacer 174 and the second spacer 176 may be formed using an etch back process. The first spacer 174 and the second spacer 176 may expose an upper surface of the second gate mask pattern 270 and an upper surface of the fin type active pattern 120.

The first spacer 174 and the second spacer 176 may include, for example, a silicon nitride film or a silicon oxynitride film, but is not limited thereto.

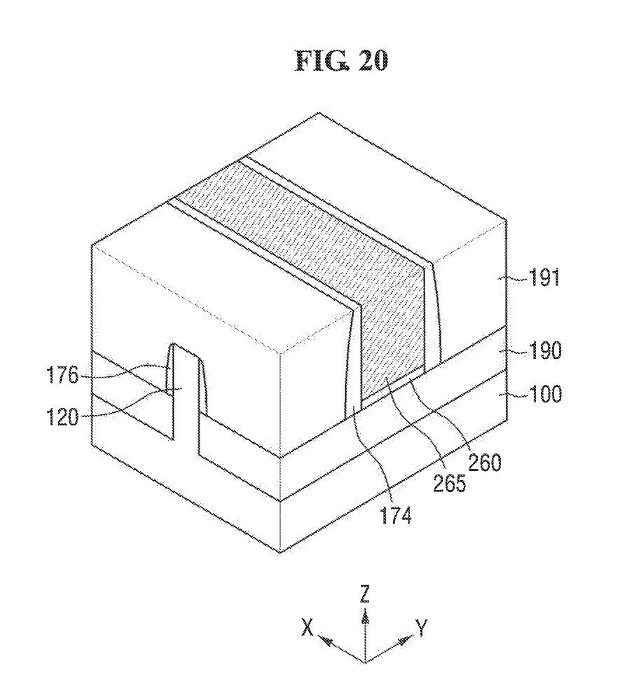

Referring to FIG. 20, a second interlayer insulating film 191 may be formed on the first spacer 174 and the second spacer 176. The second interlayer insulating film 191 may include, for example, silicon oxide, but is not limited thereto.

Then, the second interlayer insulating film 191 is planarized until the upper surface of the dummy gate electrode 265 is exposed. The second gate mask pattern 270 may be removed, and an upper surface of the dummy gate electrode 265 may be exposed.

Referring to FIG. 21, the dummy gate insulating film 260 and the dummy gate electrode 265 are removed. A trench 320 for exposing the isolation film 190 is formed,

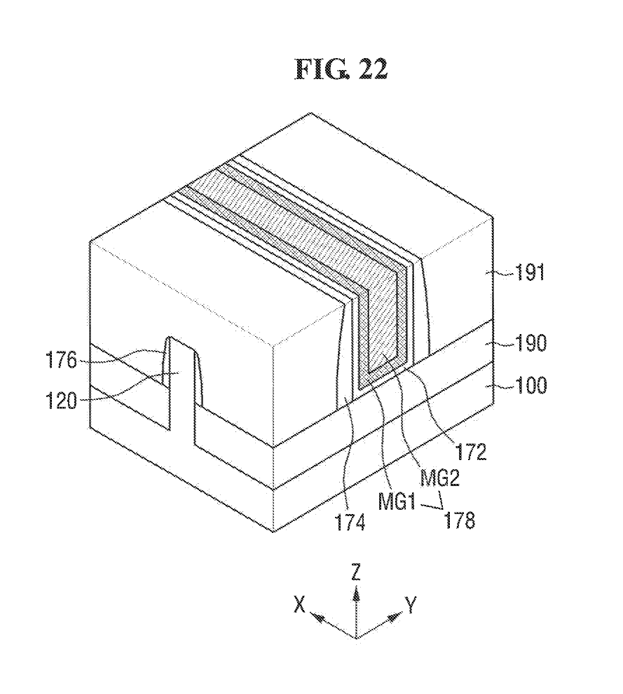

Referring to FIG. 22, a second gate insulating film 172 and the second gate electrode 178 are formed in the trench 320.

The second gate insulating film 172 may include a high-k dielectric material having a dielectric constant greater than the dielectric constant of the silicon oxide film. For example, the second gate insulating film 172 may include HfO2, ZrO2, or Ta2O5. The second gate insulating film 172 may be substantially conformally formed along a side wall and a lower surface of the trench 320.

The second gate electrode 178 may include metal layers MG1 and MG2. The second gate insulating film 172 and the first metal layer MG1 included in the second gate electrode 178 may be formed to extend in the second direction Z along the side wall of the first spacer 174. The first metal layer MG1 serves to adjust a work function, and the second metal layer MG2 serves to fill a space formed by the first metal layer MG1. For example, the first metal layer MG1 may include, for example, at least one of TiN, TaN, TiC, and TaC. Further, the second metal layer MG2 may include, for example, W or Al. Alternatively, the second gate electrode 178 may be made of Si or SiGe.

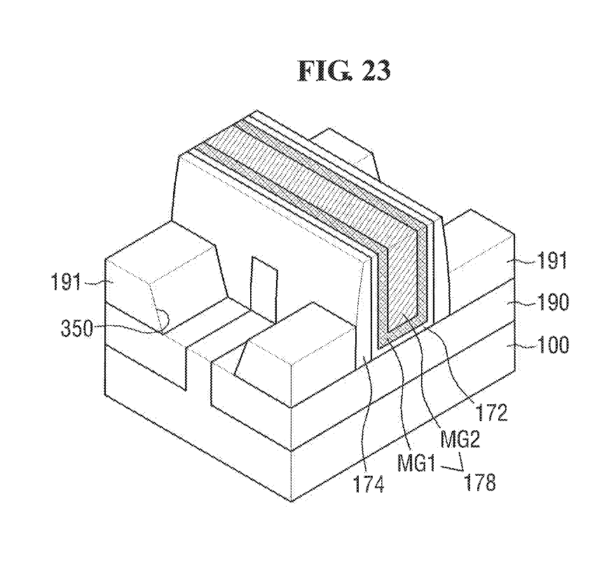

Referring to FIG. 23, a recess 350 may be formed in the fin type active pattern 120 on both sides of the second gate electrode 178.

The recess 350 may be formed in the fin type active pattern 120 on both sides of the second gate electrode 178. The side wall of the recess 350 is inclined, and the shape of the recess 350 becomes wider as it goes far from the substrate 100. The width of the recess 350 may be wider than the width of the recessed fin type active pattern 120.

Referring to FIGS. 24 to 26, a second source/drain 360 is formed in the recess 350. For example, the second source/drain 360 may be in contact with the recessed fin type active pattern 120 and may be in an elevated source/drain shape. For example, the upper surface of the second source/drain 360 may be higher than the upper surface of the second interlayer insulating film 191.

If a fin type transistor 500 is a PMOS transistor, the second source/drain 360 may include a compression stress material. For example, the compression stress material may be a material having a lattice constant greater than the lattice constant of Si, and for example, may be SiGe. The compression stress material may improve mobility of carriers of a channel region through application of compression stress to the fin type active pattern 120.

If the fin type transistor 500 is an NMOS transistor, the second source/drain 360 may be made of the same material as the material of the substrate 100 or a tensile stress material. For example, if the substrate 100 is made of Si, the first source/drain 360 may be made of Si or a material having a lattice constant greater than the lattice constant of Si (e.g., SiC).

The second source/drain 360 may be formed through an epitaxial process. The material of the second source/drain 360 may differ depending on whether the fin type transistor 500 is the PMOS or NMOS transistor. An impurity may be doped in-situ during the epitaxial process for forming the second source/drain 360.

Referring to FIG. 27, an insulating film pattern 335 covers the second gate insulating film 172 and the second gate electrode 178.

After the insulating film pattern 335 is formed, a second diffusion film 370 that includes an impurity may be formed on the insulating film pattern 335 and the fin type transistor 500.

The impurity may have, for example, the same conduction type as the conduction type of the fin type transistor 500. For example, if the fin type transistor 500 is a pFET, boron (B) that is a p-type impurity may be included, while if the tin type transistor 500 includes an nFET, phosphorous (P) that is an n-type impurity may be included. However, the present inventive concept is not limited thereto.

After the second diffusion film 370 is formed, the impurity included in the second diffusion film 370 is diffused into the second source/drain 360. For example, diffusion of the impurity may be performed through heat treatment 400 with respect to the second diffusion film 370.

The impurity may be diffused into the second source/drain 360 to reduce the resistance of the second source/drain 360. The impurity may serve to reduce the increased resistance of the second source/drain 360 due to the compression stress or tensile stress material.

The method for reducing the resistance of the second source/drain 360 through the impurity diffusion may cause little damage on the surface of the second source/drain 360 in comparison to the method for reducing the resistance using an impurity injection method such as an ion implantation method. Due to the less damage of the surface, the roughness of the source/drain surface is not increased, and the merging of two neighboring transistors may be prevented.

After the impurity is diffused, the second diffusion film 370 may be removed.

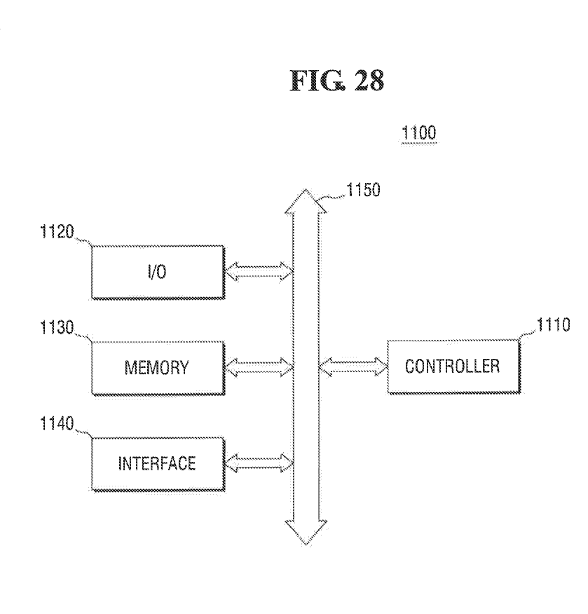

Next, referring to FIG. 28, an electronic system including a semiconductor device according to an exemplary embodiment of the present inventive concept will be described.

FIG. 28 is a block diagram of an electronic system including a semiconductor device according to an exemplary embodiment of the present inventive concept.

Referring to FIG. 28, an electronic system 1100 according to an exemplary embodiment of the present inventive concept may include a controller 1110, an input/output (I/O) device 1120, a memory 1130, an interface 1140, and a bus 1150. The controller 1110, the I/O device 1120, the memory 1130, and/or the interface 1140 may be coupled to one another through the bus 1150. The bus 1150 corresponds to paths through which data is transferred.

The controller 1110 may include at least one of a microprocessor, a digital signal processor, a microcontroller, and logic elements that may perform similar functions. The I/O device 1120 may include a keypad, a keyboard, and a display device. The memory 1130 may store data and/or commands. The interface 1140 may function to transfer the data to a communication network or receive the data from the communication network. The interface 1140 may be of a wired or wireless type. For example, the interface 1140 may include an antenna or a wire/wireless transceiver. Although not illustrated, the electronic system 1100 may further include a high-speed Dynamic Random Access Memory (DRAM) and/or a Static Random Access Memory (SRAM) as an operating memory for improving the operation of the controller 1110.

The memory 1130, the controller 1110, or the I/O device 1120 may include a semiconductor device according to an exemplary embodiment of the inventive concept.

The electronic system 1100 may be applied to a PDA (Personal Digital Assistant), a portable computer, a web tablet, a wireless phone, a mobile phone, a digital music player, a memory card, or all electronic devices that can transmit and/or receive information in wireless environments.

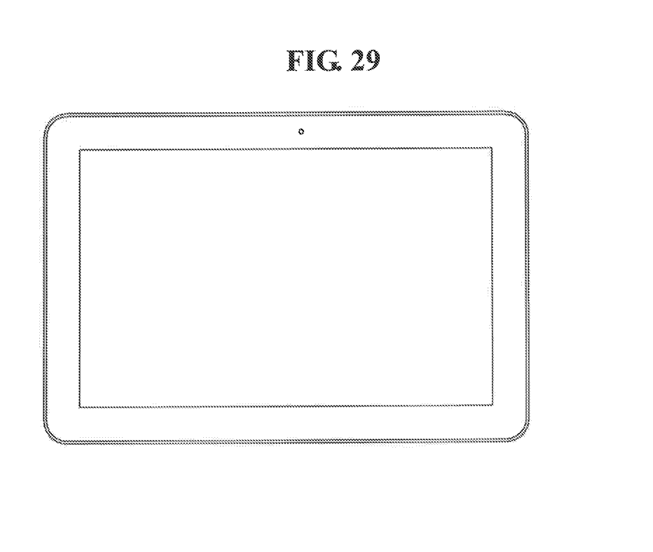

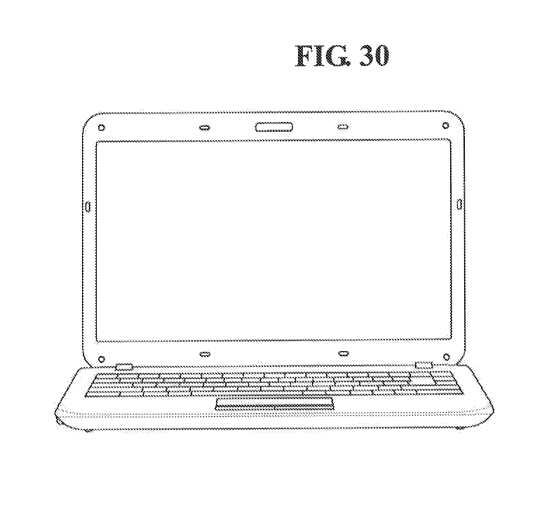

FIGS. 29 and 30 are semiconductor systems including a semiconductor device according to an exemplary embodiment of the present inventive concept. FIG. 29 illustrates a tablet Personal Computer (PC), and FIG. 30 illustrates a notebook PC. The tablet PC or the notebook PC may include a component including a semiconductor device according to an exemplary embodiment of the present inventive concept. It is apparent to those of skilled in the art that a semiconductor device according to an exemplary embodiment of the present inventive concept may be applied to other application apparatuses that have not been exemplified.

While the present inventive concept has been shown and described with reference to exemplary embodiments thereof, it will be apparent to those of ordinary skill in the art that various changes in form and detail may be made therein without departing from the spirit and scope of the inventive concept as defined by the following claims.

What is claimed is:

1. A method of fabricating a semiconductor device, comprising:
forming a fin type active pattern that projects from a substrate;
forming a diffusion film on the fin type active pattern, the diffusion film including an impurity; and
diffusing the impurity into a lower portion of the fin type active pattern to form a punch-through stopper diffusion layer.

2. The method of claim 1, wherein the diffusion film in contact with only the to lower portion of the fin type active pattern.

3. The method of claim 2, wherein the forming of the diffusion film comprises:
forming a preliminary diffusion film covering the fin type active pattern;
forming an interlayer insulating film on the preliminary diffusion film;
planarizing the interlayer insulating film and the preliminary diffusion film until the upper portion of the fin type active pattern is exposed;
forming a first mask pattern that overlaps the fin type active pattern on the fin type active pattern after the planarizing; and
etching an upper portion of the preliminary diffusion film using the first mask pattern as a mask to form the diffusion film that covers an upper portion of the substrate and the lower portion of the fin type active pattern.

4. The method of claim 3, wherein the preliminary diffusion film is selectively etched using an etchant having etching selectivity between the interlayer insulating film and the diffusion film.

5. The method of claim 4, wherein the etching of the preliminary diffusion film is performed by a wet etching process, and the forming of the diffusion film further comprises removing the interlayer insulating film after the etching of the preliminary diffusion film.

6. The method of claim 1, wherein the forming of the diffusion film comprises:
forming an insulating film which covers an upper portion of the fin type active pattern and exposes the lower portion of the tin type active pattern; and
forming the diffusion film on the insulating film and the lower portion of the fin type active pattern.

7. The method of claim 6, wherein the forming of the insulating film comprises:
forming the insulating film which covers the fin type active pattern;
forming a second mask pattern on the fin type active pattern; and
etching a lower portion of the insulating film using the second mask pattern as a mask to expose the lower portion of the fin type active pattern.

8. The method of claim 7, wherein the etching of the insulating film includes a wet etching process.

9. The method of claim 1, wherein the diffusing of the impurity into the lower portion of the fin type active pattern is performed by a heat treatment process.

10. The method of claim 1, further comprising removing the diffusion film after the forming of the punch-through stopper diffusion layer.

11. The method of claim 1, further comprising forming a transistor on the fin type active pattern after the forming the punch-through stopper diffusion layer.

12. The method of claim 11, wherein the transistor is of a first conduction type, and the impurity is of a second conduction type that is different from the first conduction type.

13. The method of claim 11, wherein the transistor comprises a source and a drain, and the source and the drain are formed in an upper portion of the fin type active pattern.

14. The method of claim 13, wherein the source and the drain are spaced apart from the punch-through stopper diffusion layer.

15. A method of fabricating a semiconductor device, comprising:
forming a fin type active pattern that projects from a substrate;
forming a diffusion film on the fin type active pattern, the diffusion film including an impurity;
diffusing the impurity into a lower portion of the fin type active pattern to form a punch-through stopper diffusion layer; and
forming a transistor that includes a source and a drain on the fin type active pattern,
wherein the source and the drain are formed in an upper portion of the fin type active pattern.

16. A method of fabricating a semiconductor device, comprising:
forming a fin type active pattern that projects from a substrate;
forming a diffusion film on the fin type active pattern, the diffusion film including a first impurity of a first conduction type and the diffusion film being in contact with a lower portion of the fin type active pattern;
forming a punch-through stopper diffusion layer by diffusing the first impurity into the lower portion of the fin type active pattern and the substrate; and
forming a source/drain of a transistor in an upper portion of the fin type active pattern, the source/drain including a second impurity of a second conduction type different from the first conduction type.

17. The method of claim 16, further comprising:
after forming the punch-through stopper diffusion, forming an isolation film on the lower portion of the fin type active pattern.

18. The method of claim 17, further comprising:
forming a gate electrode on the upper portion of the fin type active pattern and the isolation film.

19. The method of claim 16, wherein the source/drain is epitaxially formed, and the second impurity is doped in situ while the source/drain is epitaxially formed.

20. The method of claim 16, further comprising an insulating film interposed between an upper portion of the fin type active pattern and the diffusion film.
